(19) United States
(12) Patent Application Publication
(10) Pub. No.: US 2026/0047314 A1
(43) Pub. Date: Feb. 12, 2026

(54) DISPLAY DEVICE AND METHOD FOR MANUFACTURING THE SAME

(71) Applicant: Samsung Display Co., LTD., Yongin-si (KR)

(72) Inventors: Joo Hee LEE, Yongin-si (KR); Seok Hwan BANG, Yongin-si (KR); Jin Seok OH, Yongin-si (KR)

(73) Assignee: Samsung Display Co., LTD., Yongin-si (KR)

(21) Appl. No.: 19/083,856

(22) Filed: Mar. 19, 2025

(30) Foreign Application Priority Data
Aug. 9, 2024 (KR) 10-2024-0106499

(51) Int. Cl. H10K 59/80; H10K 59/12; H10K 59/122; H10K 59/19; H10K 71/60; H10K 102/00; H10K 102/10

(52) U.S. Cl. CPC H10K 59/80517; H10K 59/1201; H10K 59/122; H10K 59/19; H10K 71/60; H10K 2102/103; H10K 2102/351

(57) ABSTRACT

A display device includes a first substrate including a light emitting area and a non-light emitting area; an anode electrode disposed on the light emitting area of the substrate; a pixel defining layer disposed on the non-light emitting area of the substrate and defining an opening; a spacer disposed on the pixel defining layer; an organic layer disposed on the anode electrode; and a cathode electrode disposed on the organic layer, the anode electrode includes a first layer including a transparent conductive oxide; a second layer disposed on the first layer and including a reflective metal; a third layer disposed on the second layer and including an amorphous oxide; and a fourth layer disposed on the third layer and including a transparent conductive oxide.

### CROSS-REFERENCE TO RELATED APPLICATION(S)

This application claims priority to and benefits of Korean Patent Application No. 10-2024-0106499 under 35 U.S.C. § 119 filed on Aug. 9, 2024 in the Korean Intellectual Property Office, the entire contents of which are incorporated herein by reference.

### BACKGROUND

### 1. Technical Field

The disclosure relates to a display device and a method for manufacturing the display device.

### 2. Description of the Related Art

As an information society develops, the demand for a display device for displaying an image is increasing in various forms. The display device may be a flat panel display, such as a liquid crystal display, a field emission display, or a light emitting display panel. The light emitting display device may include an organic light emitting diode display device including an organic light emitting diode element as a light emitting element or a light emitting diode display device including an inorganic light emitting diode element such as a light emitting diode (LED) as a light emitting element.

A display device using a two stack tandem OLED technology, which stacks an upper light emitting layer on a lower light emitting layer, is being developed. The display device using the two stack tandem OLED technology may provide a high-brightness screen by combining light generated from two layers (for example, the lower light emitting layer and the upper light emitting layer).

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure solve a reliability defect caused by an anode electrode.

However, aspects of the disclosure are not restricted to those set forth herein. The above and other aspects of the disclosure will become more apparent to one of ordinary skill in the art to which the disclosure pertains by referencing the detailed description of the disclosure given below.

Details of other embodiments are included in the detailed description and drawings.

In an embodiment, a display device may include a first substrate including a light emitting area and a non-light emitting area; an anode electrode disposed on the light emitting area of the substrate; a pixel defining layer disposed on the non-light emitting area of the substrate and defining an opening; a spacer disposed on the pixel defining layer; an organic layer disposed on the anode electrode; and a cathode electrode disposed on the organic layer, wherein the anode electrode may include a first layer including a transparent conductive oxide; a second layer disposed on the first layer and including a reflective metal; a third layer disposed on the second layer and including an amorphous oxide; and a fourth layer disposed on the third layer and including a transparent conductive oxide.

In an embodiment, the third layer may be between the second layer and the fourth layer and contact the second layer and the fourth layer, and the third layer may include amorphous indium-tin-gallium-zinc-oxide (a-ITGZO).

In an embodiment, a thickness of the third layer may be less than a thickness of the second layer.

In an embodiment, the thickness of the third layer may be about 5 Angstroms or more and about 200 Angstroms or less.

In an embodiment, the second layer may include silver (Ag).

In an embodiment, the first layer and the fourth layer may include indium tin oxide (ITO).

In an embodiment, a thickness of the first layer and a thickness of the fourth layer may be less than a thickness of the second layer.

In an embodiment, the pixel defining layer may contact the first layer, the second layer, the third layer, and the fourth layer.

In an embodiment, the pixel defining layer may expose the anode electrode in a portion overlapping the opening, and the spacer may surround the opening.

In an embodiment, a portion of the spacer may protrude in an opposite direction in which the substrate may be disposed.

In an embodiment, the display device may further comprise a separator disposed in a portion overlapping the non-light emitting area, wherein the separator may be formed by recessing a portion of the pixel defining layer and a portion of the spacer in a direction toward the substrate.

In an embodiment, the organic layer may include a tandem structure including a charge generation layer, and the charge generation layer may be disposed in a portion overlapping the light emitting area and the non-light emitting area.

In an embodiment, a thickness of the charge generation layer in a portion overlapping the separator may be less by half or more than a thickness of the charge generation layer that does not overlap the separator.

In an embodiment, the separator may not overlap the anode electrode in a direction perpendicular to the substrate.

In an embodiment, a method for manufacturing a display device may include depositing an anode electrode on a substrate, heat-treating the anode electrode, and etching and removing a portion of the anode electrode; forming a pixel defining layer and a spacer covering an edge portion of the anode electrode, and heat-treating the pixel defining layer and the spacer; forming a separator by etching a portion of the pixel defining layer and the spacer; and forming an organic layer and a cathode layer on the anode electrode, wherein in the depositing of the anode electrode, the anode electrode may include a first layer, a second layer, a third layer, and a fourth layer, and the third layer may include an amorphous oxide.

In an embodiment, in the depositing of the anode electrode, the fourth layer may be entirely in an amorphous state.

In an embodiment, in the depositing of the anode electrode, the fourth layer may have a reduced crystallinity due to the amorphous oxide of the third layer.

In an embodiment, in the heat-treating of the anode electrode, the fourth layer may be entirely crystallized.

In an embodiment, after the forming of the separator, the anode electrode may not include silver eruption.

In an embodiment, an electronic device may include a display panel including a display area including a substrate including a light emitting area and a non-light emitting area, and a non-display area surrounding a periphery of the display area; an anode electrode disposed on the light emitting area of the substrate; a pixel defining layer disposed on the non-light emitting area of the substrate and defining an opening; a spacer disposed on the pixel defining layer; an organic layer disposed on the anode electrode; and a cathode electrode disposed on the organic layer, wherein the anode electrode may include a first layer including a transparent conductive oxide; a second layer disposed on the first layer and including a reflective metal; a third layer disposed on the second layer and including an amorphous oxide; and a fourth layer disposed on the third layer and including a transparent conductive oxide.

According to the display device and the method for manufacturing the same according to embodiments, as the anode electrode includes an amorphous oxide layer, the reliability defect caused by the anode electrode may be solved.

However, the effects of the embodiments are not restricted to the ones set forth herein. The above and other effects of the embodiments will become more apparent to one of daily skill in the art to which the embodiments pertain and by referencing the claims.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of a display device according to an embodiment;

FIG. 2 is a schematic cross-sectional view of the display device according to an embodiment;

FIG. 3 is a schematic plan view of a display layer of FIG. 2;

FIG. 4 is an enlarged schematic plan view of a display area of FIG. 3;

FIG. 5 is a schematic cross-sectional view illustrating light emitting elements overlapping each light emitting area of FIG. 4;

FIG. 6 is a schematic cross-sectional view taken along line X1-X1′ of FIG. 4;

FIG. 7 is an enlarged schematic cross-sectional view of an anode electrode of FIG. 6;

FIG. 8 is an enlarged schematic cross-sectional view of an anode electrode of a comparative example;

FIG. 9 is an enlarged schematic cross-sectional view of area C of FIG. 7;

FIG. 10 is an enlarged schematic cross-sectional view of area R of FIG. 8;

FIGS. 11 to 17 are schematic cross-sectional views illustrating a method for manufacturing a light emitting element layer of FIG. 6;

FIG. 18 is a block diagram of an electronic device according to an embodiment; and

FIG. 19 is a schematic diagram of an electronic device according to various embodiments.

### DETAILED DESCRIPTION OF THE EMBODIMENTS

In the following description, for the purposes of explanation, numerous given details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these given details or with one or more equivalent arrangements. Here, various embodiments do not have to be exclusive nor limit the disclosure. For example, given shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a given process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terminology used herein is for the purpose of describing embodiments and is not intended to be limiting.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

“About” or “approximately” as used herein is inclusive of the stated value and means within an acceptable range of deviation for the value as determined by one of ordinary skill in the art, considering the measurement in question and the error associated with measurement of the quantity (for example, the limitations of the measurement system). For example, “about” can mean within one or more standard deviations, or within ±30%, 20%, 10% or 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As customary in the field, an embodiment is described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of an embodiment may be physically separated into two or more interacting and discrete blocks, units, and/or modules without departing from the scope of the disclosure. Further, the blocks, units, and/or modules of an embodiment may be physically combined into more complex blocks, units, and/or modules without departing from the scope of the disclosure.

Hereinafter, embodiments will be described with reference to the accompanying drawings.

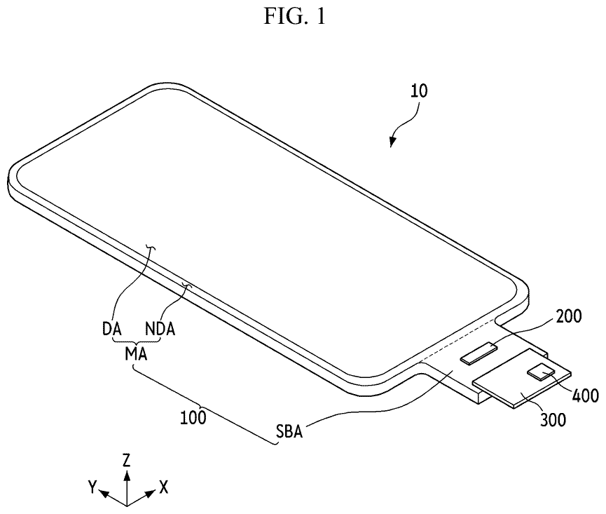

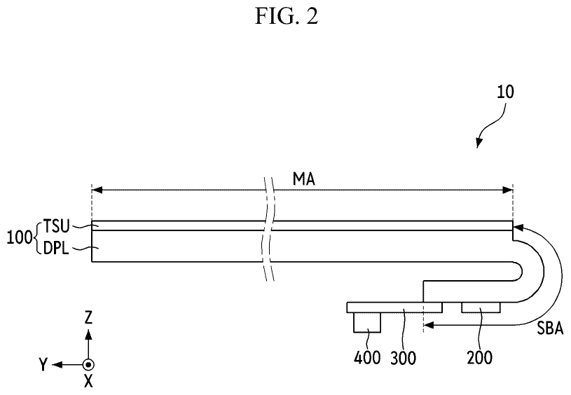

FIG. 1 is a schematic perspective view of a display device according to an embodiment. FIG. 2 is a schematic cross-sectional view of the display device according to an embodiment.

Referring to FIGS. 1 and 2, a first direction X is a direction parallel to one side or a side of a display device 10 in plan view, and refers to a direction of a short side of the display device 10. A second direction Y is a direction parallel to the other side in contact with one side or a side of the display device 10 in plan view, and refers to a direction of a long side of the display device 10. A third direction Z refers to a thickness direction of the display device 10. However, it should be understood that the directions mentioned in the embodiments refer to the relative directions, and the embodiments are not limited to the mentioned directions.

The display device 10 may include various electronic devices that provide a display screen. For example, the display device 10 may be applied to portable electronic devices such as mobile phones, smartphones, tablet personal computers (PCs), mobile communication terminals, electronic notebooks, electronic books, portable multimedia players (PMPs), navigation systems, and ultra mobile PCs (UMPCs). For example, the display device 10 may be applied to a car, a television, a laptop computer, a monitor, a billboard, or the Internet of Things (IOT). The display device 10 may be applied to wearable devices such as smart watches, watch phones, glasses-type displays, and head mounted displays (HMDs).

The display device 10 may be formed in a planar shape similar to a quadrangle. For example, the display device 10 may have a planar shape similar to a quadrangle having a short side in the first direction X and a long side in the second direction Y. A corner where the short side in the first direction X and the long side in the second direction Y meet may be rounded to have a given curvature or may have a right angled shape. The planar shape of the display device 10 is not limited to the quadrangle, and may have a shape similar to other polygons, circles, or ovals.

At least one of the front and rear surfaces of the display device 10 may be a display surface. Here, the “front surface” refers to a surface positioned on one side or a side of one plane and positioned in the third direction Z in the drawing, and the “rear surface” refers to a surface positioned on the other side of one plane and positioned in a direction opposite to the third direction Z in the drawing. The display device 10 may be a double-sided display device 10 in which display is performed on both the front and rear surfaces, but hereinafter, an embodiment in which the display surface is positioned on the front surface of the display device 10 will be described.

The display device 10 may include a display panel 100 that provides a display screen, a display driver 200, a circuit board 300, and a touch driving circuit 400. The touch driving circuit 400 is a component configured to sense a user's touch input and may be referred to as a “touch sensing device.”

The display panel 100 may be formed in a planar shape similar to a quadrangle. For example, the display panel 100 may have a planar shape similar to a quadrangle having a short side in the first direction X and a long side in the second direction Y. A corner where the short side in the first direction X and the long side in the second direction Y meet may be rounded to have a given curvature or may have a right angled shape. The planar shape of the display panel 100 is not limited to the quadrangle, and may have a shape similar to other polygons, circles, or ovals. The display panel 100 may also be flexibly formed to be flexibly bent or curved.

The display panel 100 may include a main area MA and a sub-area SBA.

The main area MA may include a display area DA including pixels displaying an image, and a non-display area NDA disposed around the display area DA. The display area DA may emit light from light emitting areas or opening areas. For example, the display panel 100 may include a pixel circuit including switching elements, a pixel defining layer defining the light emitting areas or the openings, and a self-light emitting element.

The non-display area NDA may be an area outside the display area DA. The non-display area NDA may be defined as an edge area of the main area MA of the display panel 100.

The sub-area SBA may extend from one side or a side of the main area MA. The sub-area SBA may be bent to overlap the main area MA in a third direction Z. The sub-area SBA may include a pad portion connected to the display driver 200 and the circuit board 300.

In cross-section, the display panel 100 may include a display layer DPL and a touch layer TSU stacked in the third direction Z. A detailed structure of the display layer DPL will be described later.

The touch layer TSU may be disposed on the display layer DPL, but the disclosure is not limited thereto. For example, the touch layer TSU may be formed together with the display layer DPL in an in-cell touch method. The touch layer TSU may determine whether the touch input has been made and calculate a corresponding position as touch input coordinates. The touch layer TSU may include \touch electrodes and touch lines for sensing a user's touch (or pen touch) in a capacitive manner.

The sub-area SBA of the display panel 100 may extend from one side or a side of the main area MA. The sub-area SBA may include a flexible material that may be bent, folded, rolled, or the like within the spirit and the scope of the disclosure. For example, a portion of the sub-area SBA may be bent on one side or a side of the main area MA, and another portion of the sub-area SBA extending from the bent portion of the sub-area SBA may overlap the main area MA in the third direction (Z-axis direction). The sub-area SBA may include a pad portion connected to the display driver 200 and the circuit board 300.

The display driver 200 may be disposed in the sub-area SBA of the display panel 100. The display driver 200 may be formed as an integrated circuit (IC) and mounted on the display panel 100 by a chip on plastic (COP) method or a chip on glass (COG) method.

The display driver 200 may output data signals and voltages for driving the display panel 100. The display driver 200 may supply the data voltages to data lines (not illustrated) of the display panel 100. The display driver 200 may supply a power voltage to a power line of the display panel 100 and may supply gate control signals to a gate driver.

The circuit board 300 may be disposed in the sub-area SBA of the display panel 100. Lead lines (not illustrated) of the circuit board 300 may be electrically connected to the pad portion of the display panel 100. The circuit board 300 may be a flexible film such as a flexible printed circuit board, a printed circuit board, or a chip on film.

The circuit board 300 may transmit a signal from a main circuit board (not illustrated) to the display driver 200.

The touch driving circuit 400 may be disposed in the sub-area SBA of the display panel 100. By way of example, the touch driving circuit 400 may be mounted on the circuit board 300.

The touch driving circuit 400 may determine whether a touch input is made and calculate touch coordinates, based on sensing the amount of change in capacitance between the touch electrodes. The touch driving circuit 400 may be formed as an integrated circuit (IC) and mounted on the display panel 100 by a chip on plastic (COP) method or a chip on glass (COG) method.

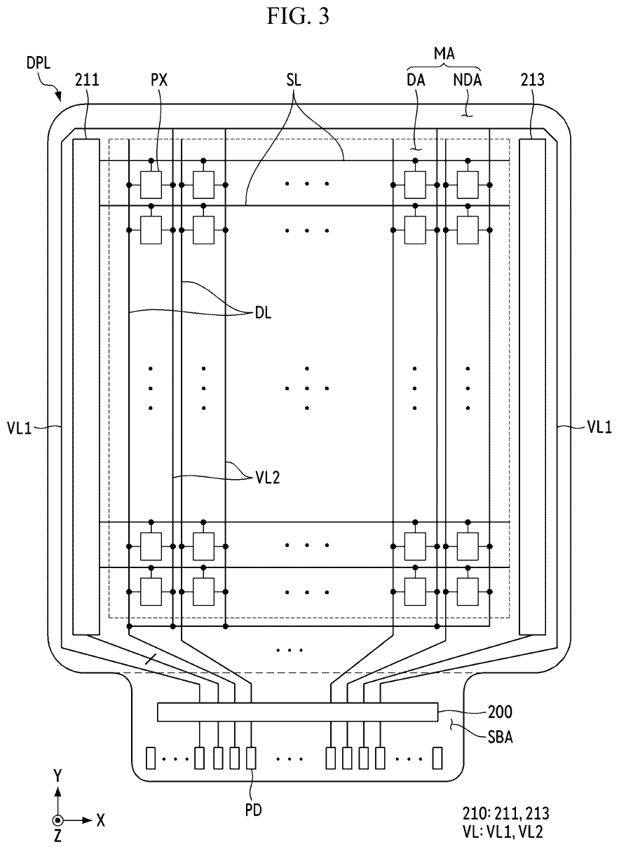

FIG. 3 is a schematic plan view of a display layer of FIG. 2.

Referring to FIG. 3, the display layer DPL may include pixels PX, scan lines SL, data lines DL, and second power lines VL2 in a portion of the main area MA that overlaps the display area DA.

Each of the pixels PX may be defined as a minimum unit emitting light. Each of the pixels PX may be connected to at least one scan line SL, at least one data line DL, and at least one power line VL. For convenience of explanation, the drawing illustrates the pixels PX aligned on the same line in the first direction X and the second direction Y, but this is only an example for indicating the circuit diagram and the disclosure is not limited thereto.

The scan lines SL may supply scan signals applied in each horizontal unit from a scan driver 210 to the pixels PX. The scan lines SL may extend in the first direction X and may be spaced apart from each other in the second direction Y.

The data lines DL may supply the data voltage received from the display driver 200 to the pixels PX. The data lines DL may extend in the second direction Y and may be spaced apart from each other in the first direction X.

The second power lines VL2 may supply a power voltage received from a first power line VL1 to the pixels PX. The power voltage may be at least one of a driving voltage, an initialization voltage, and a reference voltage. The second power lines VL2 may extend in the second direction Y and may be spaced apart from each other in the first direction X.

The display layer DPL may include the first power line VL1 and the scan driver 210 in a portion of the main area MA that overlaps the non-display area NDA.

The first power line VL1 may supply the power voltage received from the display driver 200 to the pixels PX through the second power line VL2.

The scan driver 210 may include a first scan driver 211 and a second scan driver 213. The first scan driver 211 may be disposed on one side or a side (for example, a left side) of the display layer DPL, and the second scan driver 213 may be disposed on the other side (for example, a right side) of the display layer DPL, but the disclosure is not limited thereto. Each of the first scan driver 211 and the second scan driver 213 may receive a scan control signal from the display driver 200, generate scan signals according to the scan control signal, and output the scan signals to the scan lines SL.

The display layer DPL may include a display driver 200 and pad electrodes PD in a portion overlapping the sub-area SBA. The pad electrodes PD may be positioned to be spaced apart from each other in the first direction X, and each pad electrode PD may be connected to each different line. The description of the display driver 200 is omitted.

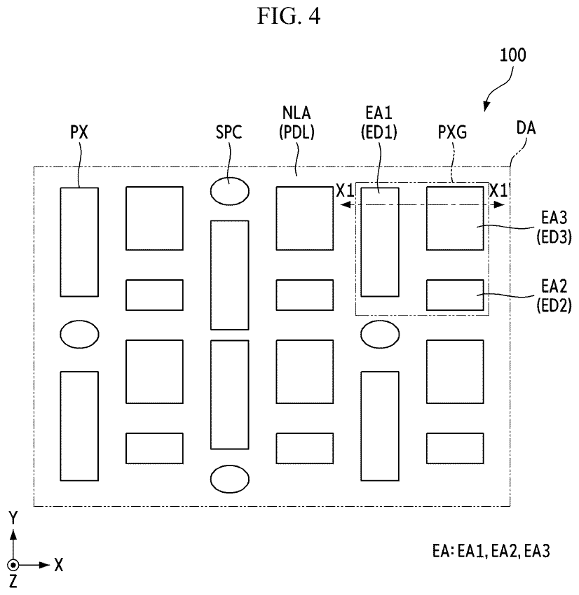

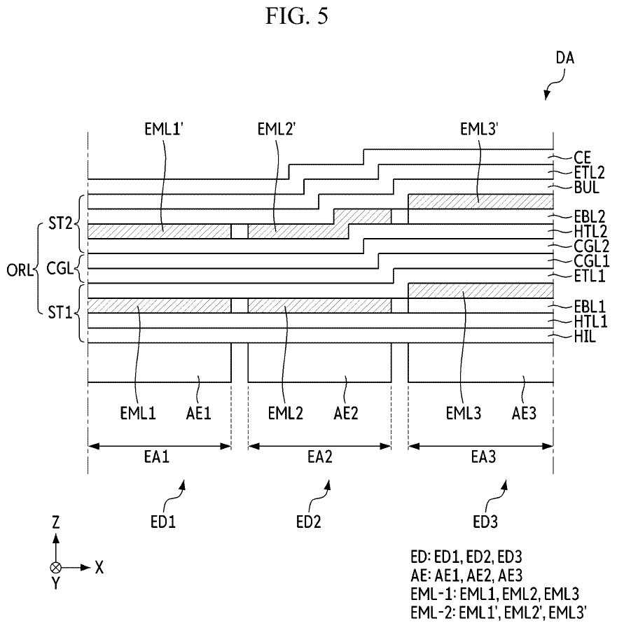

FIG. 4 is an enlarged schematic plan view of a display area of FIG. 3 and FIG. 5 is a schematic cross-sectional view illustrating light emitting elements overlapping each light emitting area of FIG. 4.

Referring to FIG. 4, the display panel 100 according to an embodiment may include a light emitting area EA and a non-light emitting area NLA in a portion overlapping the display area DA.

The light emitting areas EA may include a first light emitting area EA1, a second light emitting area EA2, and a third light emitting area EA3 that emit light of different colors. As an example, the first light emitting area EA1 may emit blue light, the second light emitting area EA2 may emit red light, and the third light emitting area EA3 may emit green light, but the disclosure is not limited thereto. The color of light emitted from each of the first to third light emitting areas EA1, EA2, and EA3 may vary depending on the type of organic layer (‘ORL’ in FIG. 5) described below.

The first light emitting area EA1 and the second light emitting area EA2 may be positioned on the same line in the first direction X and may be spaced apart from each other. The first light emitting area EA1 and the third light emitting area EA3 may be adjacent to each other in the first direction X and may be spaced apart from each other. The second light emitting area EA2 and the third light emitting area EA3 may be adjacent to each other in the second direction Y and may be spaced apart from each other. However, the arrangement of each of the first to third light emitting areas EA1, EA2, and EA3 is not limited thereto and may be freely adjusted according to required characteristics.

Each of the first to third light emitting areas EA1, EA2, and EA3 may have a quadrangular shape. However, the shape of each of the first to third light emitting areas EA1, EA2, and EA3 is not limited thereto and may be freely adjusted according to required characteristics.

In an embodiment, at least one first light emitting area EA1, at least one second light emitting area EA2, and at least one third light emitting area EA3 disposed to be adjacent to each other may form one pixel group PXG. The pixel group PXG may be a minimum unit that emits white light. The type and/or number of each of the first to third light emitting areas EA1, EA2, and EA3 constituting the pixel group PXG may vary depending on the embodiments.

The non-light emitting area NLA may be disposed to surround the light emitting area EA. The non-light emitting area NLA may assist in preventing the light emitted from each of the first to third light emitting areas EA1, EA2, and EA3 from being mixed.

A pixel defining layer PDL and a spacer SPC may be positioned in a portion overlapping the non-light emitting area NLA. The pixel defining layer PDL may serve to partition the light emitting area EA and the non-light emitting area NLA, and the spacer SPC may assist in preventing a lower substructure overlapping the light emitting area EA from being damaged by external factors.

Referring to FIG. 5 in addition to FIG. 4, the light emitting element ED overlapping the display area DA may include a first light emitting element ED1, a second light emitting element ED2, and a third light emitting element ED3. By way of example, the first light emitting element ED1 may be positioned in a portion overlapping the first light emitting area EA1, the second light emitting element ED2 may be positioned in a portion overlapping the second light emitting area EA2, and the third light emitting element ED3 may be positioned in a portion overlapping the third light emitting area EA3. The first light emitting element ED1, the second light emitting element ED2, and the third light emitting element ED3 may emit light of different colors.

The first light emitting element ED1 according to an embodiment may include a first anode electrode AE1, an organic layer ORL, and a cathode electrode CE, the second light emitting element ED2 may include a second anode electrode AE2, an organic layer ORL, and a cathode electrode CE, and the third light emitting element ED3 may include a third anode electrode AE3, an organic layer ORL, and a cathode electrode CE.

The anode electrode AE according to an embodiment may include a first anode electrode AE1, a second anode electrode AE2, and a third anode electrode AE3. The first anode electrode AE1, the second anode electrode AE2, and the third anode electrode AE3 may be spaced apart from each other in the first direction X.

The anode electrode AE may be a reflective electrode. As an example, the anode electrode AE may include a metal layer such as Ag, Mg, Al, Pt, Pd, Au, Ni, Nd, Ir, and Cr, and may further include a metal oxide layer stacked on the metal layer. The detailed structure of the anode electrode AE will be described later.

The organic layer ORL according to an embodiment may be positioned on the anode electrode AE. The organic layer ORL may be formed in a tandem structure. In other words, the organic layer ORL may include a first stack ST1, a charge generation layer CGL, and a second stack ST2 stacked in the third direction Z.

The first stack ST1 according to an embodiment may be disposed on the anode electrode AE. The first stack ST1 may include a hole injection layer HIL, a first hole transporting layer HTL1, a first electron block layer EBL1, a lower light emitting layer EML-1, and a first electron transporting layer ETL1.

The hole injection layer HIL according to an embodiment may be disposed in contact with the anode electrode AE. The hole injection layer HIL may be a common layer positioned so as to be continuously connected to the portions overlapping the first light emitting area EA1, the second light emitting area EA2, and the third light emitting area EA3. The hole injection layer HIL may include a hole injection material that facilitates hole injection. Depending on the embodiments, the hole injection layer HIL may be omitted.

As an example, the hole injection material may be made of one or more selected from the group consisting of copper phthalocyanine (CuPc), poly(3,4)-ethylenedioxythiophene (PEDOT), polyaniline (PANI), and N,N-dinaphthyl-N,N′-diphenyl benzidine (NPD), but is not limited thereto.

The first hole transporting layer HTL1 according to an embodiment may be positioned in contact with the hole injection layer HIL. The first hole transporting layer HTL1 may be a common layer positioned so as to be continuously connected to the portions overlapping the first light emitting area EA1, the second light emitting area EA2, and the third light emitting area EA3. The first hole transporting layer HTL1 may include a hole transporting material that facilitates hole transport.

As an example, the hole transporting material may include carbazole-based derivatives such as N-phenylcarbazole and polyvinylcarbazole; fluorene-based derivatives, triphenylamine-based derivatives such as TPD(N,N′-bis(3-methylphenyl)-N,N′-diphenyl-[1,1-biphenyl]-4,4′-diamine), and TCTA(4,4′,4″-tris(N-carbazolyl)triphenylamine), NPB(N,N′-di(1-naphthyl)-N,N′-diphenylbenzidine), TAPC(4,4′-Cyclohexylidene bis[N,N-bis(4-methylphenyl)benzenamine]), or the like, but is not limited thereto.

The first electron block layer EBL1 according to an embodiment may be positioned in contact with the first hole transporting layer HTL1. Depending on embodiments, the first electron block layer EBL1 and the first hole transporting layer HTL1 may be formed as a single layer.

The first electron block layer EBL1 may prevent electrons generated in the lower light emitting layer EML-1 from passing to the first hole transporting layer HTL1. The first electron block layer EBL1 may be formed by including the hole transporting material described above and a metal or metal compound. It is illustrated in the drawing that the first electron block layer EBL1 is positioned only in the portion overlapping the third light emitting area EA3, but the disclosure is not limited thereto.

The lower light emitting layer EML-1 according to an embodiment may be positioned on the first electron block layer EBL1 and the first hole transporting layer HTL1. The lower light emitting layer EML-1 may include a first lower light emitting layer EML1, a second lower light emitting layer EML2, and a third lower light emitting layer EML3. The first lower light emitting layer EML1, the second lower light emitting layer EML2, and the third lower light emitting layer EML3 may be spaced apart from each other in the first direction X.

The first lower light emitting layer EML1, the second lower light emitting layer EML2, and the third lower light emitting layer EML3 may emit different colors. For example, the first lower light emitting layer EML1 may emit blue light, the second lower light emitting layer EML2 may emit red light, and the third lower light emitting layer EML3 may emit green light.

The first electron transporting layer ETL1 according to an embodiment may be disposed on the lower light emitting layer EML-1. The first electron transporting layer ETL1 may be a common layer positioned so as to be continuously connected to the portions overlapping the first light emitting area EA1, the second light emitting area EA2, and the third light emitting area EA3. The first electron transporting layer ETL1 may include an electron transporting material that facilitates electron transport.

As an example, the electron transporting material may include Alq3 (Tris(8-hydroxyquinolinato)aluminum), TPBi (1,3,5-Tri (1-phenyl-1H-benzo[d]imidazol-2-yl)phenyl), BCP (2,9-Dimethyl-4,7-diphenyl-1,10-phenanthroline), Bphen (4,7-Diphenyl-1,10-phenanthroline), TAZ (3-(4-Biphenylyl)-4-phenyl-5-tert-butylphenyl-1,2,4-triazole), NTAZ (4-(Naphthalen-1-yl)-3,5-diphenyl-4H-1,2,4-triazole), tBu-PBD (2-(4-Biphenylyl)-5-(4-tert-butylphenyl)-1,3,4-oxadiazole), BAlq (Bis(2-methyl-8-quinolinolato-N1,O8)-(1,1′-Biphenyl-4-olato)aluminum), Bebq2 (berylliumbis(benzoquinolin-10-olate), ADN (9,10-di(naphthalene-2-yl) anthracene), and mixtures thereof, but is not limited thereto.

The charge generation layer CGL according to an embodiment may be disposed on the first stack ST1. The charge generation layer CGL may be a common layer that extends to and continuously disposed in the first light emitting area EA1, the second light emitting area EA2, and the third light emitting area EA3.

The charge generation layer CGL may serve to adjust a charge balance between the first stack ST1 and the second stack ST2. In other words, the charge generation layer CGL may be disposed between the first stack ST1 and the second stack ST2, thereby increasing emission efficiency of the light emitting element ED and lowering a driving voltage thereof.

The charge generation layer CGL may include a first charge generation layer CGL1 and a second charge generation layer CGL2. The first charge generation layer CGL1 according to an embodiment may be positioned closer to the anode electrode AE than the second charge generation layer CGL2, and may supply electrons to the lower light emitting layer EML-1. The second charge generation layer CGL2 according to an embodiment may be positioned closer to the cathode electrode CE than the first charge generation layer CGL1, and may supply holes to an upper light emitting layer EML-2.

The second stack ST2 according to an embodiment may be disposed on the charge generation layer CGL. The second stack ST2 may include a second hole transporting layer HTL2, a second electron block layer EBL2, an upper light emitting layer EML-2, a buffer layer BUL, and a second electron transporting layer ETL2.

The second hole transporting layer HTL2 according to an embodiment may be disposed in contact with the charge generation layer CGL. The second hole transporting layer HTL2 may be a common layer positioned so as to be continuously connected to the portions overlapping the first light emitting area EA1, the second light emitting area EA2, and the third light emitting area EA3.

The second hole transporting layer HTL2 and the first hole transporting layer HTL1 may be made of a same material, or the second hole transporting layer HTL2 may also include one or more other materials. The second hole transporting layer HTL2 may be made as a single layer or layers.

The second electron block layer EBL2 may be positioned on the second hole transporting layer HTL2. According to embodiments, the second electron block layer EBL2 and the second hole transporting layer HTL2 may also be formed as a single layer.

The second electron block layer EBL2 may include a hole transporting material and a metal or a metal compound to prevent electrons generated in the upper light emitting layer EML-2 from passing to the second hole transporting layer HTL2. It is illustrated in the drawing that the second electron block layer EBL2 is positioned only in the portion overlapping the third light emitting area EA3, but the disclosure is not limited thereto.

The upper light emitting layer EML-2 according to an embodiment may be positioned on the second electron block layer EBL2 and the second hole transporting layer HTL2. The upper light emitting layer EML-2 may include a first upper light emitting layer EML1′, a second upper light emitting layer EML2′, and a third upper light emitting layer EML3′. The first upper light emitting layer EML1′, the second upper light emitting layer EML2′, and the third upper light emitting layer EML3′ may be spaced apart from each other in the first direction X.

Each of the first upper light emitting layer EML1′, the second upper light emitting layer EML2′, and the third upper light emitting layer EML3′ may overlap each of the first lower light emitting layer EML1, the second lower light emitting layer EML2, and the third lower light emitting layer EML3 in the third direction Z.

The first upper light emitting layer EML1′, the second upper light emitting layer EML2′, and the third upper light emitting layer EML3′ may emit different colors. For example, the first upper light emitting layer EML1′ may emit blue light, the second upper light emitting layer EML2′ may emit red light, and the third upper light emitting layer EML3′ may cmit green light.

In other words, the light finally emitted from the organic layer ORL may be blue light in the first light emitting area EA1, red light in the second light emitting area EA2, and green light in the third light emitting area EA3.

The material included in the lower light emitting layer EML-1 and the upper light emitting layer EML-2 may be made of a low-molecular organic material. In another example, the material included in the lower light emitting layer EML-1 and the upper light emitting layer EML-2 may be made of high-molecular organic material that is commonly used.

The buffer layer BUL according to an embodiment may be disposed on the upper light emitting layer EML-2. The buffer layer BUL may be a common layer positioned so as to be continuously connected to the portions overlapping the first light emitting area EA1, the second light emitting area EA2, and the third light emitting area EA3.

The buffer layer BUL may prevent holes from flowing from the upper light emitting layer EML-2 toward the cathode electrode CE. The buffer layer BUL may include a hole transporting material, but is not limited thereto.

The second electron transporting layer ETL2 according to an embodiment may be disposed on the buffer layer BUL. The second electron transporting layer ETL2 may be a common layer positioned so as to be continuously connected to the portions overlapping the first light emitting area EA1, the second light emitting area EA2, and the third light emitting area EA3.

The second electron transporting layer ETL2 may be made of a same material and the same structure as the first electron transporting layer ETL1, or may also include one or more materials selected from the materials included in the first electron transporting layer ETL1. The second electron transporting layer ETL2 may be made as a single layer or layers.

The cathode electrode CE according to an embodiment may be positioned in contact with the organic layer ORL. The cathode electrode CE may be a common layer positioned so as to be continuously connected to the portions overlapping the first light emitting area EA1, the second light emitting area EA2, and the third light emitting area EA3.

The cathode electrode CE may have semi-permeability or permeability.

In an embodiment, in case that the cathode electrode CE has the semi-permeability, the cathode electrode CE may include Ag, Mg, Cu, Al, Pt, Pd, Au, Ni, Nd, Ir, Cr, Li, Ca, LiF/Ca, LiF/Al, Mo, Ti, or a compound or mixture thereof, for example, a mixture of Ag and Mg.

In an embodiment, in case that the cathode electrode CE has the permeability, the cathode electrode CE may include transparent conductive oxide (TCO). As an example, the cathode electrode CE may include tungsten oxide (WₓO_{y}), titanium oxide (TiO₂), indium tin oxide (ITO), indium zinc oxide (IZO), zinc oxide (ZnO), indium tin zinc oxide (ITZO), magnesium oxide (MgO), or the like within the spirit and the scope of the disclosure.

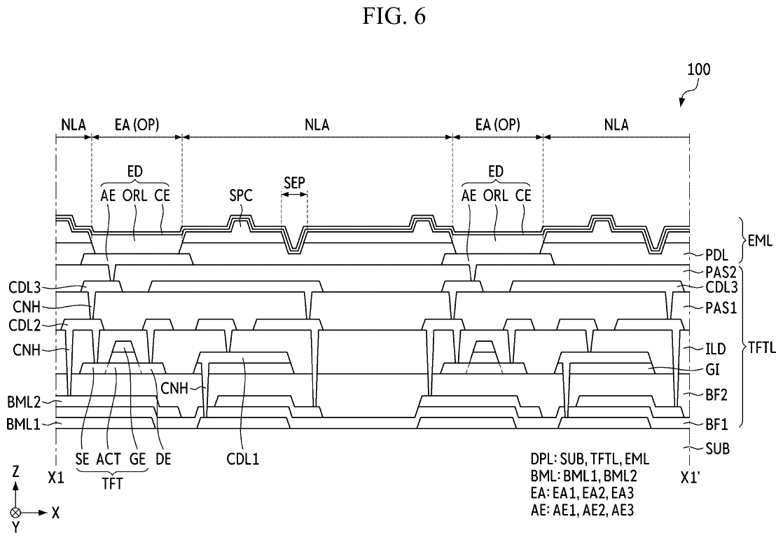

FIG. 6 is a schematic cross-sectional view taken along line X1-X1′ of FIG. 4.

Referring to FIGS. 5 and 6, the display panel 100 according to an embodiment may include a display layer DPL, and in cross-section, the display layer DPL may include a substrate SUB, a thin film transistor layer TFTL, and a light emitting element layer EML. Depending on the embodiment, the display layer DPL may further include a thin film encapsulation layer and/or a touch layer.

The substrate SUB may be a base substrate or a base member. The substrate SUB may be a flexible substrate that is bendable, foldable, rollable, or the like within the spirit and the scope of the disclosure. For example, the substrate SUB may include a polymer resin such as polyimide PI, but is not limited thereto. The substrate SUB may also include a glass material or a metal material.

The thin film transistor layer TFTL may be positioned on the substrate SUB. The thin film transistor layer TFTL may include a first lower metal layer BML1, a first buffer layer BF1, a second lower metal layer BML2, a second buffer layer BF2, a thin film transistor TFT, a first conductive layer CDL1, a gate insulating layer GI, an interlayer insulating layer ILD, a second conductive layer CDL2, a first passivation layer PAS1, a third conductive layer CDL3, and a second passivation layer PAS2.

The first lower metal layer BML1 may be disposed on the substrate SUB. The first lower metal layer BML1 may be disposed to overlap at least one of the thin film transistor TFT and/or the first conductive layer CDL1 in the third direction Z. The first lower metal layer BML1 may prevent light from entering an active layer ACT of the thin film transistor TFT, and may be electrically connected to the first conductive layer CDL1 to perform a function of stabilizing the characteristics of the first conductive layer CDL1.

The first lower metal layer BML1 may be formed as a single layer or multi-layer made of any one of molybdenum (Mo), aluminum (Al), chromium (Cr), gold (Au), titanium (Ti), nickel (Ni), neodymium (Nd), and copper (Cu), or an alloy thereof.

The first buffer layer BF1 may be disposed on the first lower metal layer BML1. The first buffer layer BF1 may cover (e.g., entirely cover) the substrate SUB and the first lower metal layer BML1. The first buffer layer BF1 may include an inorganic film capable of preventing permeation of air or moisture. For example, the first buffer layer BF1 may include inorganic films alternately stacked with each other.

The second lower metal layer BML2 may be disposed on the first buffer layer BF1. The second lower metal layer BML2 may be disposed to overlap at least one of the thin film transistor TFT and/or the first conductive layer CDL1 in the third direction Z. The second lower metal layer BML2 may prevent light from entering the active layer ACT of the thin film transistor TFT, and may be electrically connected to the thin film transistor TFT to perform a function of stabilizing the characteristics of the thin film transistor TFT. The second lower metal layer BML2 and the first lower metal layer BML1 may include a same material.

The second buffer layer BF2 may be positioned on the first buffer layer BF1 and the second lower metal layer BML2. The second buffer layer BF2 may include an inorganic film capable of preventing permeation of air or moisture. For example, the second buffer layer BF2 may include inorganic films alternately stacked with each other.

The thin film transistor TFT may be disposed on the second buffer layer BF2. The thin film transistor TFT may be a driving transistor of the pixel circuit. The thin film transistor TFT may include an active layer ACT, a source electrode SE, a drain electrode DE, and a gate electrode GE.

The active layer ACT may be disposed on the second buffer layer BF2. The active layer ACT may overlap the lower metal layer BML and the gate electrode GE in the third direction Z. The active layer ACT may be insulated from the gate electrode GE by the gate insulating layer GI. In a portion of the active layer ACT, a material of the active layer ACT may become a conductor to form the source electrode SE and the drain electrode DE.

The gate electrode GE may be disposed on the gate insulating layer GI. The gate electrode GE may overlap the active layer ACT with the gate insulating layer GI disposed between the gate electrode GE and the active layer ACT in the third direction Z.

The first conductive layer CDL1 may be spaced apart from the gate electrode GE. The first conductive layer CDL1 may overlap the lower metal layer BML with the gate insulating layer GI disposed between the first conductive layer CDL1 and the lower metal layer BML in the third direction Z. The first conductive layer CDL1 may be electrically connected to the first lower metal layer BML1 through a contact hole CNH penetrating through the gate insulating layer GI, the second buffer layer BF2, and the first buffer layer BF1.

The interlayer insulating layer ILD may cover the gate electrode GE, the first conductive layer CDL1, and the gate insulating layer GI. The interlayer insulating layer ILD may include an inorganic film capable of preventing permeation of air or moisture. For example, the interlayer insulating layer ILD may include inorganic films alternately stacked with each other.

The second conductive layer CDL2 may be disposed on the interlayer insulating layer ILD. The second conductive layer CDL2 may include various lines disposed in the display area DA.

A portion of the second conductive layer CDL2 may be electrically connected to the source electrode SE of the thin film transistor TFT and the second lower metal layer BML2 through a contact hole CNH penetrating through the interlayer insulating layer ILD and the second buffer layer BF2, and another portion of the second conductive layer CDL2 may be electrically connected to the drain electrode DE of the thin film transistor TFT through a contact hole CNH penetrating through the interlayer insulating layer ILD. The other portion of the second conductive layer CDL2 may be electrically connected to the first conductive layer CDL1 through the contact hole CNH penetrating through the interlayer insulating layer ILD.

The first passivation layer PAS1 may be positioned on the interlayer insulating layer ILD and may cover the second conductive layer CDL2. The first passivation layer PAS1 may perform a function of an insulating film and may protect the second conductive layer CDL2.

The third conductive layer CDL3 may be disposed on the first passivation layer PAS1. The third conductive layer CDL3 may be a connection electrode that electrically connects the second conductive layer CDL2 and the anode electrode AE. The third conductive layer CDL3 may be electrically connected to the second conductive layer CDL2 through a contact hole CNH penetrating through the first passivation layer PAS1.

The second passivation layer PAS2 may be positioned on the first passivation layer PAS1 and may cover the third conductive layer CDL3. The second passivation layer PAS2 may perform a function of an insulating film and may protect the third conductive layer CDL3.

The light emitting element layer EML may be disposed on the thin film transistor layer TFTL. The light emitting element layer EML may include a light emitting element ED, a pixel defining layer PDL, a spacer SPC, and a separator SEP.

The light emitting element ED may be positioned on the second passivation layer PAS2 and may include an anode electrode AE, an organic layer ORL, and a cathode electrode CE. The detailed structure of the anode electrode AE will be described later.

A portion of the organic layer ORL included in the light emitting element ED may be positioned in a portion overlapping the light emitting area EA and the non-light emitting area NLA. In a process of manufacturing the organic layer ORL, a portion of the organic layer ORL may be formed by a fine metal mask, but other portions thereof may be disposed (e.g., entirely deposited) without a separate fine metal mask. Therefore, a portion of the organic layer ORL may cover (e.g., entirely cover) the pixel defining layer PDL and may be positioned to overlap the spacer SPC and the separator SEP. The detailed structure of the organic layer ORL has already been mentioned in FIG. 5 and will be thus omitted.

The cathode electrode CE included in the light emitting element ED may be positioned in a portion overlapping the light emitting area EA and the non-light emitting area NLA. As described above, the cathode electrode CE, which is the common electrode, may cover (e.g., entirely cover) the pixel defining layer PDL and may be positioned to overlap the spacer SPC and the separator SEP. The cathode electrode CE positioned in the portion overlapping the light emitting area EA and the non-light emitting area NLA may be uniform within a thickness of a process deviation (within about 5%).

The pixel defining layer PDL may be positioned on the second passivation layer PAS2 in a portion overlapping the non-light emitting area NLA. The pixel defining layer PDL may define an opening OP and partition the light emitting area EA and the non-light emitting area NLA. The pixel defining layer PDL may be positioned to surround an edge (or edge portion) of the anode electrode AE and expose the anode electrode AE in a portion overlapping the opening OP.

The pixel defining layer PDL may also perform a surface planarization function by including organic materials such as an acrylic resin, an epoxy resin, a phenolic resin, a polyamide resin, and a polyimide resin.

The spacer SPC may be disposed on the pixel defining layer PDL in a portion overlapping the non-light emitting area NLA. A portion of the spacer SPC may protrude in the third direction Z on the pixel defining layer PDL.

The spacer SPC may protect the light emitting element layer EML and the thin film transistor layer TFTL from physical shock caused from one side or a side in the third direction Z during the process of manufacturing the display panel 100.

The spacers SPC and the pixel defining layer PDL may be made of a same material. Depending on the embodiment, the spacer SPC may be formed simultaneously with the pixel defining layer PDL or may be separately formed on the pixel defining layer PDL.

The separator SEP may be positioned in a portion overlapping the non-light emitting area NLA. The separator SEP may be formed by removing a portion of the pixel defining layer PDL and spacer SPC during the manufacturing process. In other words, the separator SEP may refer to a portion of the pixel defining layer PDL and spacer SPC that is recessed in a direction toward the substrate SUB. The manufacturing process thereof will be described later.

In general, in case that the charge generation layers (CGL in FIG. 5) included in each of the light emitting elements ED adjacent to each other are connected to each other to a certain thickness or more, a leakage current defect may occur. As a solution for solving the leakage current defect, the charge generation layer (CGL in FIG. 5) may be formed using a fine metal mask, but this may cause problems of increased cost and reduced manufacturing case.

Therefore, the display panel 100 according to an embodiment may form the charge generation layer (CGL in FIG. 5) with a low thickness in a portion overlapping the separator SEP by forming the separator SEP between the light emitting elements ED adjacent to each other. This may be caused by the separator SEP having a profile that is recessed in the direction toward the substrate SUB.

For example, the thickness of the charge generation layer CGL positioned in the portion overlapping the separator SEP may be less than or equal to half the thickness of the charge generation layer CGL positioned in a portion that does not overlap the separator SEP.

In an embodiment, the thickness of the charge generation layer CGL positioned in the portion overlapping the separator SEP may have a height of about 30% or less of the thickness of the charge generation layer CGL positioned in the portion that does not overlap the separator SEP, but is not limited thereto. As used herein height may also be a thickness.

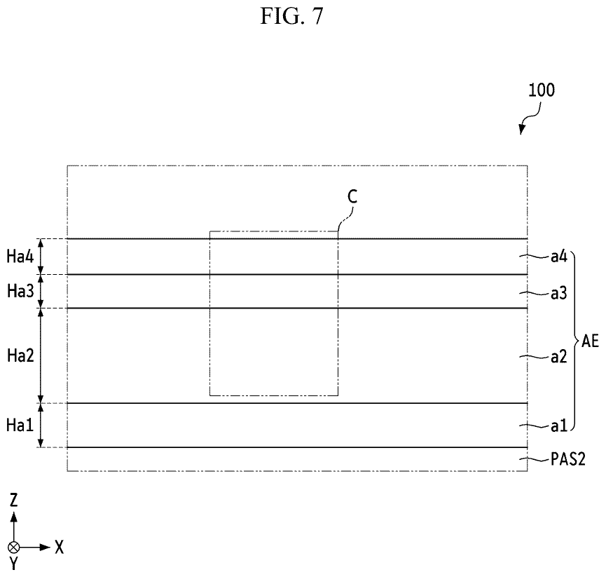

FIG. 7 is an enlarged schematic cross-sectional view of an anode electrode of FIG. 6. As used herein height may also be a thickness.

Referring to FIG. 7, the anode electrode AE included in the display panel 100 according to an embodiment may include a first layer a1, a second layer a2, a third layer a3, and a fourth layer a4. The first layer a1, the second layer a2, the third layer a3, and the fourth layer a4 may be sequentially stacked in the third direction Z.

The first layer a1 of the anode electrode AE is a light transmitting layer and may include a transparent conductive oxide (TCO). For example, the first layer a1 may include at least one of indium oxide, tin oxide, zinc oxide, gallium oxide, and silicon oxide. As an example, the first layer a1 may be indium tin oxide (ITO), but is not limited thereto.

In an embodiment, a height Ha1 of the first layer a1 may be about 10 Angstroms or more and about 300 Angstroms or less.

The second layer a2 of the anode electrode AE may be a light reflective layer. For example, the second layer a2 may include at least one of silver (Ag), an alloy of silver (Ag), gold (Au), an alloy of gold (Au), aluminum (Al), an alloy of aluminum (Al), copper (Cu), and an alloy of copper (Cu). As an example, the second layer a2 of the anode electrode AE may be silver (Ag), but is not limited thereto.

A height Ha2 of the second layer a2 may be higher than the height Ha1 of the first layer a1.

In an embodiment, the height Ha2 of the second layer a2 may be about 500 Angstroms or more and about 1500 Angstroms or less.

The first layer a1 of the anode electrode AE may cover (e.g., entirely cover) one surface or a surface of the second layer a2, thereby solving a silver migration defect caused during the process of manufacturing the anode electrode AE.

As the display panel 100 according to an embodiment may include the pixel defining layer PDL, the spacer SPC, and the separator SEP, multiple thermal processes and etching processes may be performed during the manufacturing process. Therefore, the anode electrode AE included in the display panel 100 may be required to have a structure that may be robust to the thermal process and etching process.

The anode electrode AE according to an embodiment may include the third layer a3 to minimize damage caused by the etching process and thermal process. The third layer a3 of the anode electrode AE may be positioned on the second layer a2. The third layer a3 may cover (e.g., entirely cover) the second layer a2.

The third layer a3 of the anode electrode AE is positioned in contact between the second layer a2 and the fourth layer a4, thereby solving a silver (Ag) eruption defect of the anode electrode AE and a partial crystallization defect of the fourth layer a4 that occur during the manufacturing process. A detailed description thereof will be provided later.

The third layer a3 of the anode electrode AE may include an amorphous conductive oxide. As an example, the third layer a3 may be amorphous indium-tin-gallium-zinc-oxide (a-ITGZO), but is not limited thereto.

A height Ha3 of the third layer a3 may be lower than the height Ha2 of the second layer a2.

In an embodiment, the height Ha3 of the third layer a3 may be about 5 Angstroms or more and about 200 Angstroms or less.

The fourth layer a4 of the anode electrode AE is a light transmitting layer and may include a transparent conductive oxide. For example, the fourth layer a4 may include at least one of indium oxide, tin oxide, zinc oxide, gallium oxide, and silicon oxide. As an example, the fourth layer a4 may be indium tin oxide (ITO), but is not limited thereto.

A height Ha4 of the fourth layer a4 may be lower than the height Ha2 of the second layer a2.

In an embodiment, the height Ha4 of the fourth layer a4 may be about 5 Angstroms or more and about 200 Angstroms or less.

Referring to FIGS. 5 to 7, the pixel defining layer PDL of the display panel 100 may be in contact with and cover the first layer a1, the second layer a2, the third layer a3, and the fourth layer a4 of the anode electrode AE.

The organic layer ORL of the display panel 100 may be in contact with the fourth layer a4 of the anode electrode AE, and may overlap the first layer a1, the second layer a2, the third layer a3, and the fourth layer a4 of the anode electrode AE in the third direction Z.

The separator SEP of the display panel 100 may not overlap the first layer a1, the second layer a2, the third layer a3, and the fourth layer a4 of the anode electrode AE in the third direction Z.

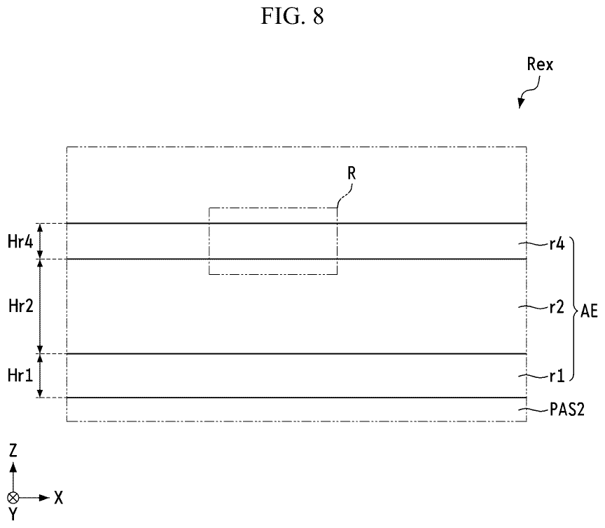

FIG. 8 is an enlarged schematic cross-sectional view of an anode electrode of a comparative example.

Referring to FIG. 8, a comparative example Rex may include an anode electrode AE including a first layer r1, a second layer r2, and a fourth layer r4. In other words, the comparative example Rex may differ from the display panel 100 in that it does not include the third layer a3 included in the anode electrode AE of the display panel 100. In other words, in the comparative example Rex, the fourth layer r4 may be positioned in direct contact with the second layer r2.

The first layer r1 included in the comparative example Rex may have a same material and structural characteristics as the first layer a1 of the display panel 100, the second layer r2 may have a same material and structural characteristics as the second layer a2 of the display panel 100, and the fourth layer r4 may have a same material and structural characteristics as the fourth layer a4 of the display panel 100.

In an embodiment, a height Hr1 of the first layer r1 may be about 10 Angstroms or more and about 300 Angstroms or less, a height Hr2 of the second layer r2 may be about 500 Angstroms or more and about 1500 Angstroms or less, and a height Hr4 of the fourth layer r4 may be about 5 Angstroms or more and about 200 Angstroms or less.

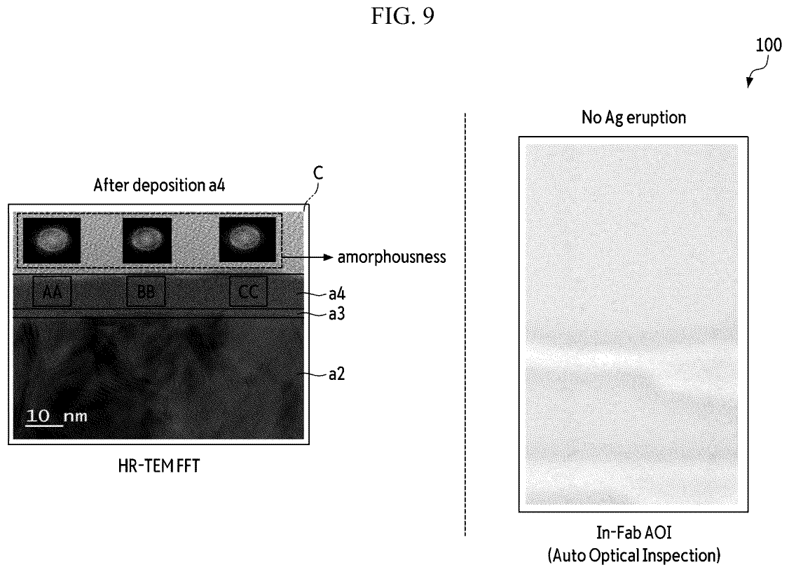

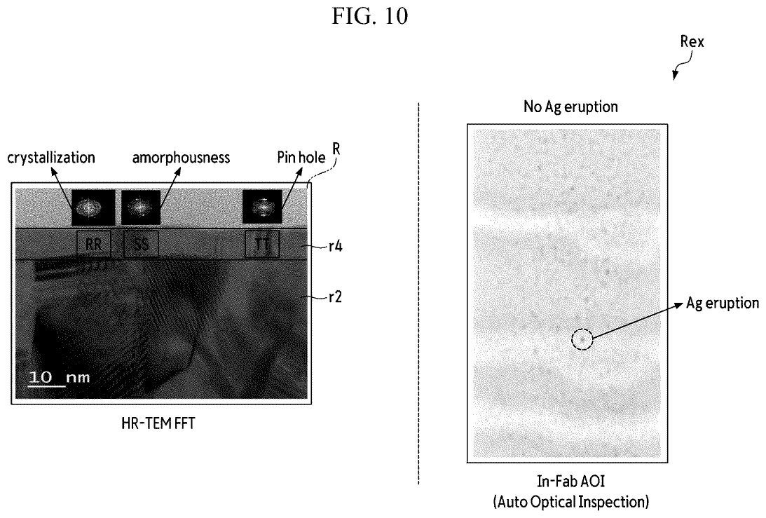

FIG. 9 is an enlarged schematic cross-sectional view of area C of FIG. 7 and FIG. 10 is an enlarged schematic cross-sectional view of area R of FIG. 8. FIGS. 9 and 10 illustrate a High Resolution-TEM Fast Fourier Transform (HR-TEM FFT) image measured before the crystallization process after deposition of the fourth layer a4 of the display panel 100 and the fourth layer r4 of the comparative example Rex and an In-Fab AOI image measured after the separator SEP of FIG. 6 was formed.

Referring to FIG. 9, it may be confirmed with reference to the HR-TEM FFT image after deposition of the fourth layer a4 included in the display panel 100 that the fourth layer a4 is uniformly formed in an amorphous shape in a first area AA, a second area BB, and the third area CC immediately after the deposition.

The display panel 100 according to an embodiment may slow down a crystallization speed of the fourth layer a4 by depositing the third layer a3 including amorphous indium-tin-gallium-zinc-oxide (a-ITGZO) with a uniform thickness between the second layer a2 including silver (Ag) and the fourth layer a4 including the transparent conductive oxide (TCO).

As a result, the fourth layer a4 may be uniformly deposited in an amorphous state without being partially crystallized during the manufacturing process. The fourth layer a4 deposited in the amorphous state may be uniformly crystallized after a subsequent heat treatment process.

Referring to the In-Fab AOI image measured after the separator (SEP in FIG. 6) was formed, it may be confirmed that no silver eruption defect is observed on the anode electrode AE of the display panel 100. This may mean that the anode electrode AE is uniformly crystallized, so that micro pin-holes and/or partial crystallization defects are not formed.

Referring to FIG. 10 in comparison with FIG. 9, referring to the HR-TEM FFT image after deposition of the fourth layer r4 included in the comparative example Rex, in the fourth layer r4, a crystallized shape was observed in the first area RR, an amorphous shape was observed in the second area SS, and a micro pin hole was observed together with the crystallized shape in the third area TT. The micro pin holes may be formed due to differences in nuclear growth rates resulting from the partial crystallization shape.

The anode electrode AE included in the comparative example Rex may have a high crystallization rate even though the fourth layer r4 does not perform a crystallization process, because being formed so that the fourth layer r4 including the transparent conductive oxide is in direct contact with the second layer r2 including silver (Ag), Therefore, a portion of the fourth layer r4 may be partially crystallized immediately after deposition. The partial crystallization may be randomly formed.

Referring to the In-Fab AOI image measured after the separator (SEP in FIG. 6) was formed, silver (Ag) eruption was observed on the anode electrode AE included in the comparative example Rex. The silver (Ag) eruption may be caused by a portion of the silver (Ag) included in the second layer r2 being erupted to the outside due to the micro pin holes formed in the fourth layer r4 and the partial crystallization defects.

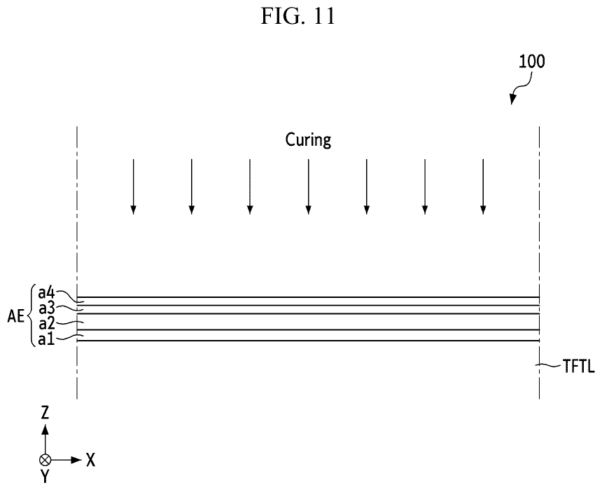

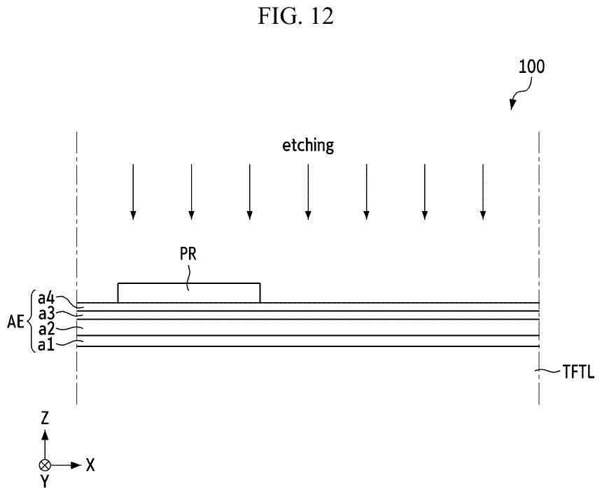

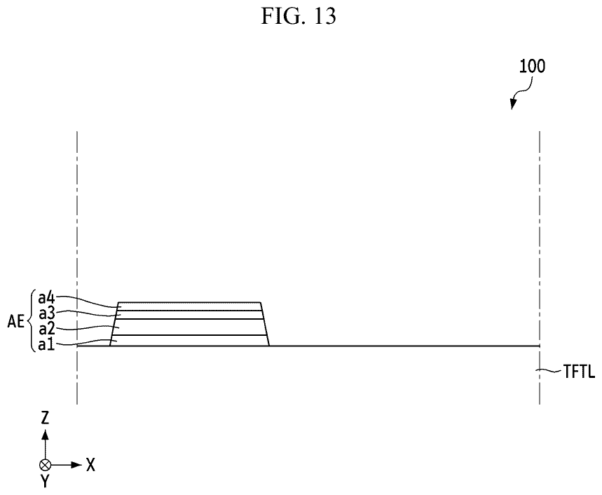

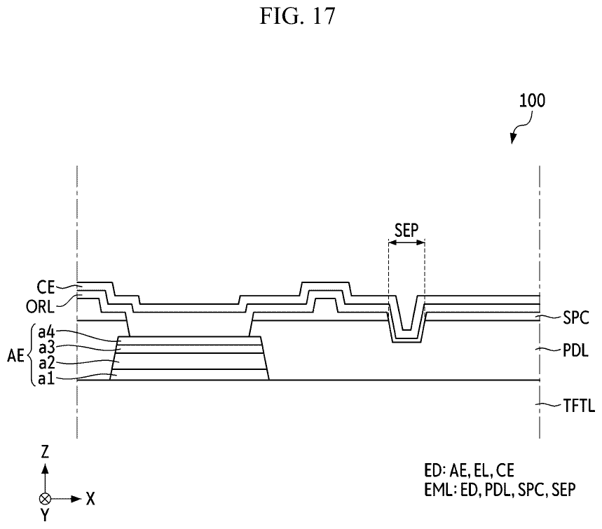

FIGS. 11 to 17 are schematic cross-sectional views illustrating a method for manufacturing a light emitting element layer of FIG. 6.

Referring to FIGS. 11 to 13, an anode electrode AE may be formed (e.g., entirely formed) on a thin film transistor layer TFTL. The detailed structure of the thin film transistor layer TFTL may be the same as that illustrated in FIG. 6.

In the process, the anode electrode AE may include a first layer a1, a second layer a2, a third layer a3, and a fourth layer a4 sequentially stacked in the third direction Z. The first layer a1, the second layer a2, the third layer a3, and the fourth layer a4 may be formed by a sputtering process, and may be formed (e.g., entirely formed) without a separate mask. In the process, a height of the second layer a2 may be formed higher than heights of the first layer a1, the third layer a3, and the fourth layer a4. In the process, the fourth layer a4 of the anode electrode AE may be uniformly deposited in an amorphous state. The redundant descriptions will be omitted.

The anode electrode AE is crystallized by performing a heat treatment process (curing). In the process, the fourth layer a4 may have a uniformly crystallized shape. The redundant descriptions will be omitted.

A photoresist PR may be formed on the fourth layer a4, and an etching process may be performed. In the present process, a photoresist PR may be formed by exposing a portion of the anode electrode AE, and a portion of the anode electrode AE that does not overlap the photoresist PR may be removed. As a result, the anode electrode AE may have a shape patterned into an island shape. In the process, the anode electrode AE may not include the silver eruption defect even in case that exposed to the etching process. The redundant descriptions will be omitted.

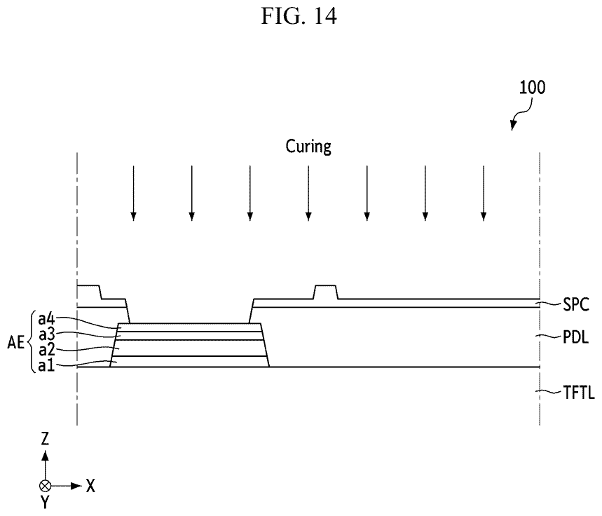

Referring to FIG. 14, a pixel defining layer PDL may be formed on the anode electrode AE, and a spacer SPC may be formed on the pixel defining layer PDL. The pixel defining layer PDL and the spacer SPC may be positioned to surround an edge (or edge portion) of the anode electrode AE. In the process, the anode electrode AE may not include a reliability defect even in case that exposed to the high temperature heat treatment process. The redundant descriptions will be omitted.

A heat treatment process (curing) may be performed on the pixel defining layer PDL and the spacer SPC. In the process, a portion of the anode electrode AE may be exposed to high temperature.

For convenience of explanation, the pixel defining layer PDL and the spacer SPC are described and illustrated as being formed in a continuous process, but are not limited thereto. Depending on the embodiment, the pixel defining layer PDL and the spacer SPC may also be formed in different processes. For example, in case that the pixel defining layer PDL and the spacer SPC are formed in different processes, the heat treatment process (curing) may be performed after the formation of the pixel defining layer PDL and may also be performed after the formation of the spacer SPC.

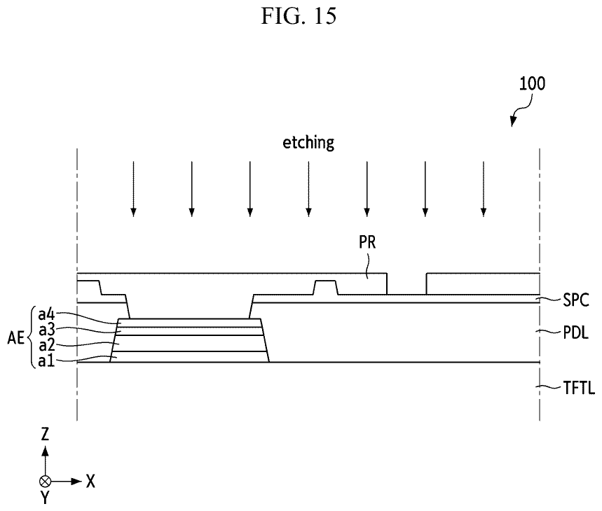

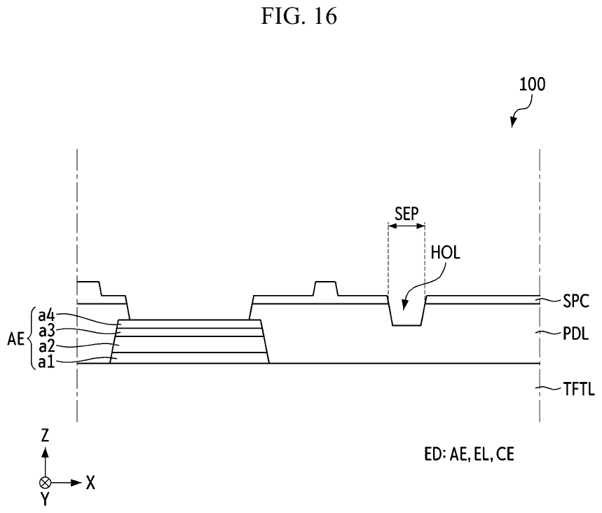

Referring to FIGS. 15 and 16, a photoresist PR may be formed on the spacer SPC, and an etching process may be performed. In the process, the photoresist PR may cover completely the anode electrode AE.

In the process, portions of the spacer SPC and the pixel defining layer PDL that do not overlap the photoresist PR may be removed, and as a result, holes HOL may occur in portions of the spacer SPC and the pixel defining layer PDL. The hole HOL formed in a portion of the spacer SPC and pixel defining layer PDL may be defined as a separator SEP.

An organic layer ORL may be formed on the anode electrode AE so as to be in contact with the anode electrode AE. In the process, a common layer included in the organic layer ORL may be formed (e.g., entirely formed). However, a height of the common layer included in the organic layer ORL in a portion overlapping the separator SEP may be formed to be lower by half or more the thickness of the common layer included in the organic layer ORL in a portion that does not overlap the separator SEP. The redundant descriptions may be omitted.

A cathode electrode CE may be formed (e.g., entirely formed) on the organic layer ORL. In the process, a height of the cathode electrode CE in a portion overlapping the separator SEP may be uniformly formed within a process deviation from a height of the cathode electrode CE in a portion that does not overlap the separator SEP. As a result, the light emitting element layer EML illustrated in FIG. 6 may be formed.

The display device according to an embodiment can be applied to various electronic devices. The electronic device may include the display device described above, and may further include modules or devices having additional functions in addition to the display device.

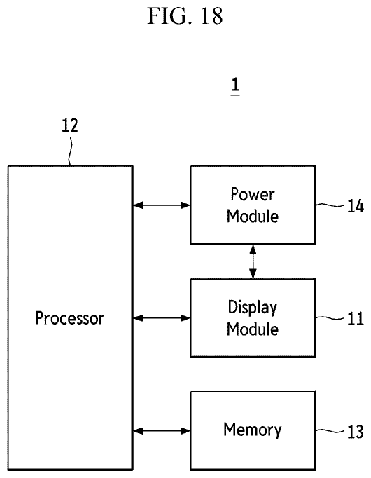

FIG. 18 is a block diagram of an electronic device according to an embodiment.

Referring to FIG. 18, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 1 according to the embodiment may be included in the display device 10 according to the embodiments. Some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 1 other than the display device 10.

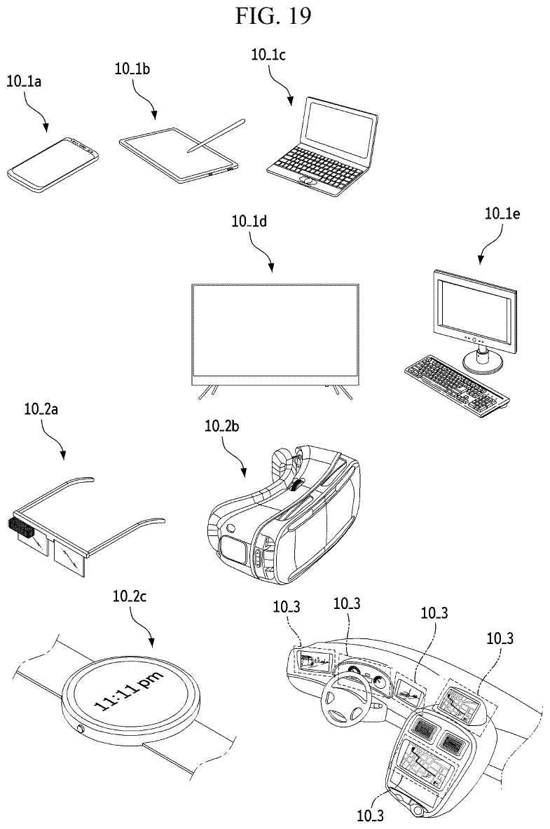

FIG. 19 is a schematic diagram of an electronic device according to various embodiments.

Referring to FIG. 19, various electronic devices to which display devices 10 according to embodiments are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

As described above, the anode electrode AE included in the display panel 100 may be robust to the etching process and the heat treatment process in the process of manufacturing the anode electrode AE by including the third layer a3 including the amorphous oxide. Therefore, the reliability defect caused by the anode electrode AE of the display panel 100 according to an embodiment may be solved.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate including a light emitting area and a non-light emitting area;
an anode electrode disposed on the light emitting area of the substrate;
a pixel defining layer disposed on the non-light emitting area of the substrate and defining an opening;
a spacer disposed on the pixel defining layer;
an organic layer disposed on the anode electrode; and
a cathode electrode disposed on the organic layer,
wherein the anode electrode includes:
a first layer including a transparent conductive oxide;
a second layer disposed on the first layer and including a reflective metal;
a third layer disposed on the second layer and including an amorphous oxide; and
a fourth layer disposed on the third layer and including a transparent conductive oxide.

2. The display device of claim 1, wherein the third layer is disposed between the second layer and the fourth layer and contacts the second layer and the fourth layer, and
the third layer includes amorphous indium-tin-gallium-zinc-oxide (a-ITGZO).

3. The display device of claim 2, wherein a thickness of the third layer is less than a thickness of the second layer.

4. The display device of claim 3, wherein the thickness of the third layer is about 5 Angstroms or more and about 200 Angstroms or less.

5. The display device of claim 4, wherein the second layer includes silver (Ag).

6. The display device of claim 4, wherein the first layer and the fourth layer include indium tin oxide (ITO).

7. The display device of claim 1, wherein a thickness of the first layer and a thickness of the fourth layer are less than a thickness of the second layer.

8. The display device of claim 1, wherein the pixel defining layer contacts the first layer, the second layer, the third layer, and the fourth layer.

9. The display device of claim 8, wherein the pixel defining layer exposes the anode electrode in a portion overlapping the opening, and
the spacer surrounds the opening.

10. The display device of claim 9, wherein a portion of the spacer protrudes in an opposite direction in which the substrate is disposed.

11. The display device of claim 1, further comprising:
a separator disposed in a portion overlapping the non-light emitting area,
wherein the separator is formed by recessing a portion of the pixel defining layer and a portion of the spacer in a direction toward the substrate.

12. The display device of claim 11, wherein the organic layer includes a tandem structure including a charge generation layer, and
the charge generation layer is disposed in a portion overlapping the light emitting area and the non-light emitting area.

13. The display device of claim 12, wherein a thickness of the charge generation layer in a portion overlapping the separator is less by half or more than a thickness of the charge generation layer that does not overlap the separator.

14. The display device of claim 11, wherein the separator does not overlap the anode electrode in a direction perpendicular to the substrate.

15. A method for manufacturing a display device, the method comprising:
depositing an anode electrode on a substrate, heat-treating the anode electrode, and etching and removing a portion of the anode electrode;
forming a pixel defining layer and a spacer covering an edge portion of the anode electrode, and heat-treating the pixel defining layer and the spacer;
forming a separator by etching a portion of the pixel defining layer and the spacer; and
forming an organic layer and a cathode layer on the anode electrode,
wherein in the depositing of the anode electrode, the anode electrode includes a first layer, a second layer, a third layer, and a fourth layer, and
the third layer includes an amorphous oxide.

16. The method of claim 15, wherein in the depositing of the anode electrode, the fourth layer is entirely in an amorphous state.

17. The method of claim 16, wherein in the depositing of the anode electrode, the fourth layer has a reduced crystallinity due to the amorphous oxide of the third layer.

18. The method of claim 17, wherein in the heat-treating of the anode electrode, the fourth layer is entirely crystallized.

19. The method of claim 15, wherein after the forming of the separator, the anode electrode does not include silver eruption.

20. An electronic device comprising:
a display panel including a display area including a substrate including a light emitting area and a non-light emitting area, and a non-display area surrounding a periphery of the display area;
an anode electrode disposed on the light emitting area of the substrate;
a pixel defining layer disposed on the non-light emitting area of the substrate and defining an opening;
a spacer disposed on the pixel defining layer;
an organic layer disposed on the anode electrode; and
a cathode electrode disposed on the organic layer,
wherein the anode electrode includes:
a first layer including a transparent conductive oxide;
a second layer disposed on the first layer and including a reflective metal;
a third layer disposed on the second layer and including an amorphous oxide; and
a fourth layer disposed on the third layer and including a transparent conductive oxide.
